(19) United States
(12) Patent Application Publication
(10) Pub. No.: US 2019/0341742 A1
(43) Pub. Date: Nov. 7, 2019

(54) PLASMON-ACTIVATED MONOLITHIC CAVITIES FOR SELF-INJECTION LOCKING OF LASERS

(71) Applicant: OEWAVES, INC., PASADENA, CA (US)

(72) Inventors: Anatoliy A. SAVCHENKOV, Glendale, CA (US); Andrey B. MATSKO, Pasadena, CA (US)

(21) Appl. No.: 16/398,023

(22) Filed: Apr. 29, 2019

Related U.S. Application Data
(60) Provisional application No. 62/665,402, filed on May 1, 2018.

(51) Int. Cl. H01S 5/10; H01S 5/065

(52) U.S. Cl. CPC H01S 5/1046; H01S 5/0657

(57) ABSTRACT

The disclosure relates in some aspects to an open dielectric resonator with nanoparticles secured on its outer surface, where the nanoparticles are located, sized and/or shaped to increase an amount of backscattered light in the resonator to provide substantially lossless, coherent backscattering of light. In some examples, fine particles are used instead of nanoparticles. Other features relate to a laser system having a plasmon-activated cavity optically coupled to a laser where the plasmon-activated cavity is configured to (a) receive a laser beam, (b) scatter the laser beam in accordance with a plasmon resonance, and (c) feed at least a portion of the laser beam back to the laser for self-injection locking of the laser. The plasmon-activated cavity may be a dielectric resonator with surface particles configured to stabilize the laser to a frequency of a plasmon mode to reduce a linewidth of the laser.

### PRIORITY CLAIM AND CROSS-REFERENCE TO RELATED APPLICATION

This patent document claims the priority of U.S. Provisional Application No. 62/665,402, entitled “PLASMON-ACTIVATED MONOLITHIC CAVITIES FOR SELF-INJECTION LOCKING ENHANCEMENT,” filed on May 1, 2018, the entire disclosure of which is incorporated by reference herein.

### FIELD OF THE DISCLOSURE

Various aspects of the disclosure relate to monolithic micro-cavity devices such as open dielectric optical resonators formed using monolithic micro-cavities, and in particular to self-injection locking of lasers using plasmon-activated micro-cavities.

### BACKGROUND

Self-injection locking of a semiconductor laser to an external cavity is a useful and practical technique to narrow the laser linewidth. For many applications, the external cavity should ideally have a very narrowband and be highly reflective. Recently developed crystalline whispering gallery mode micro-cavity crystalline resonators can achieve very low optical loss, making them good candidates for use as the external cavity of a self-injection locked semiconductor laser.

The back-reflection of crystalline resonators, however, can be irregular (due to such factors as the distribution of random intracavity defects, random nano-sized scratches from polishing slurry, dust particles having various albedo values randomly deposited on the surface, and absorption properties within the bulk of the resonator and its surfaces). The random combination of such factors can result in an uncontrolled backscatter reflection value and, consequently, an unpredictable locking range value. For instance, a C-band distributed feedback (DFB) laser mode-matched to a MgF₂ monolithic resonator may show a locking range between 2 to 5 milliamps (mA), while one matched to CaF₂ may show a locking range of 0.5-1.5 mA. Such low injection locking range values combined with the high dispersion of the values remains a significant practical problem in many applications. A main source of the locking range problem is a low and unpredictable amount of backscatter from the resonator.

Often, native backscattering within a resonator is insufficient for the task of self-injection locking of a laser. Therefore, backscattering is often boosted via an external far-field reflector, a nearfield reflector, or random or periodic Bragg-gratings. Exemplary systems that boost backscattering using a far-field reflector (such as, e.g., U.S. Pat. No. 8,605,760) may include a second evanescent coupler (e.g. a prism), a collimating lens and a mirror. While such systems can be efficient and offer much flexibility, they also can be relatively complex.

Note that an evanescent coupler produces a diverging Gaussian beam whose properties depend on the shape and material of the resonator. The beam does not start to diverge immediately from the contact point between the coupler and resonator. Instead the beam diverges and the waist of the beam grows slowly along the axis of the beam. The distance along the propagation direction of a beam from the waist to the point where the area of the cross section is doubled is called Rayleigh distance. A mirror placed within this distance reflects the beam back with very little deformation of the phase front or amplitude profile. An evanescent coupler that contains a mirror placed very close to the resonator-coupler contact point is called a nearfield reflector. Such a design is relatively simple since there is no need for a lens or optical alignment. On the other hand, there is little or no flexibility since any error in manufacturing is permanent.

A properly designed series of periodic or random scratches at the chamfer of the resonator scatters the circulating light backwards. (See, e.g., U.S. Pat. No. 7,991,025.) Among the advantages of such a technique is that the reflector is permanent and can be designed for any target bandwidth. A possible disadvantage is that the technique may require a precise micromachining capability, otherwise the yield might be low.

It would be desirable to provide monolithic micro-cavities that have a predictable amount of backscattering for use, for example, to self-injection lock lasers or to achieve other goals or advantages. It would also be desirable to provide dielectric resonators configured to increase an amount of backscattered light within the dielectric resonator for use in self-injection locking of lasers or to achieve other goals or advantages.

### SUMMARY

This document discloses, among other features, various systems, methods and apparatus that provide or use plasmon-activated monolithic cavities for self-injection locking of lasers, where the monolithic cavities may be, for example, open dielectric resonators with nanoparticles deposited on their outside surfaces to increase an amount of plasmon resonance within the dielectric resonator to, e.g., provide a predictable amount of backscattering and to reduce a linewidth of a laser or to achieve other goals.

In one aspect, a resonator apparatus includes: a dielectric resonator; and particles positioned on a surface of the dielectric resonator, the particles configured to increase an amount of backscattered light within the dielectric resonator. In some examples, the particles are nanoparticles. In other examples, the particles are fine particles.

In another aspect, an optical system includes: a coherent light source configured to provide a coherent light beam having a coherent light frequency; and a plasmon-activated cavity, optically coupled to the coherent light source, and configured to receive a portion of the coherent light beam, scatter the portion of the coherent light beam in accordance with a plasmon resonance to form a scattered beam, and feed at least a portion of the scattered beam back to the coherent light source.

In yet another aspect, a method of controlling a coherent light source includes: generating a coherent light beam having a coherent light frequency; coupling a portion of the coherent light beam into a plasmon-activated cavity; scattering the portion of the coherent light beam within the plasmon-activated cavity in accordance with a plasmon resonance to form a scattered beam; and feeding at least a portion of the scattered beam back to the coherent light source from the plasmon-activated cavity.

### BRIEF DESCRIPTION OF THE DRAWINGS

FIG. 1 illustrates an example of an optical open dielectric resonator with nanoparticles, such as gold nanoparticles, deposited on its outer surface.

FIG. 2 is a graph showing the effective albedo of an exemplary gold nanoparticle.

FIG. 3 illustrates a solid spherical open dielectric resonator with nanoparticles deposited on its outer surface.

FIG. 4 illustrates a solid disc-shaped open dielectric resonator with nanoparticles deposited on its outer surface.

FIG. 5 illustrates a ring-shaped open dielectric resonator with nanoparticles deposited on its outer surface.

FIG. 6 illustrates a tunable open dielectric resonator with nanoparticles deposited to its outer surface, and also having electrodes for tuning the resonator.

FIG. 7 illustrates a laser optically coupled to an open dielectric resonator through an optical coupler.

FIG. 8 is a high-level block diagram of a resonator apparatus having a dielectric resonator and particles positioned on the dielectric resonator.

FIG. 9 is a high-level block diagram of a laser system having a laser and a plasmon-activated cavity, which may be configured as a dielectric resonator cavity.

FIG. 10 is a block diagram illustrating additional components of an exemplary laser system, particularly various control signal components for applying a direct current (DC) electrical control signal to the plasmon-activated cavity via electrodes.

FIG. 11 is a block diagram illustrating components of an exemplary laser system, particularly various other control signal components for applying microwave or radio-frequency (RF) control signals to the plasmon-activated cavity via an antenna.

FIG. 12 is a block diagram illustrating components of an exemplary laser system, particularly various other control signal components for applying temperature or pressure control signals to the plasmon-activated cavity via suitable transducers.

FIG. 13 summarizes an exemplary method for controlling a laser using a plasmon-activated cavity, such as a dielectric resonator with surface nanoparticles.

FIG. 14 further summarizes an exemplary method for controlling a laser using a plasmon-activated cavity, wherein nanoparticles are deposited on the cavity surface.

### DETAILED DESCRIPTION

In the following description, specific details are given to provide a thorough understanding of the various aspects of the disclosure. However, it will be understood by one of ordinary skill in the art that aspects may be practiced without these specific details. For example, components may be shown in block diagrams to avoid obscuring aspects in unnecessary detail. In other instances, well-known components, structures and techniques are not shown in detail to avoid obscuring aspects of the disclosure.

The word “exemplary” is used herein to mean “serving as an example, instance, or illustration.” Any implementation or aspect described herein as “exemplary” is not necessarily to be construed as preferred or advantageous over other aspects of the disclosure. Likewise, an aspect is an implementation or example. Reference in the specification to “an aspect,” “one aspect,” “some aspects,” “various aspects,” or “other aspects” means that a particular feature, structure, or characteristic described in connection with the aspects is included in at least some aspects, but not necessarily all aspects, of the present techniques. The various appearances of “an aspect,” “one aspect,” or “some aspects” are not necessarily all referring to the same aspects. Elements or aspects from an aspect can be combined with elements or aspects of another aspect.

In the following description and claims, the term “coupled” may mean that two or more elements are in direct physical or electrical contact. However, “coupled” may also mean that two or more elements are not in direct contact with each other, but yet still co-operate or interact with each other.

Not all components, features, structures, characteristics, etc. described and illustrated herein need be included in a particular aspect or aspects. If the specification states a component, feature, structure, or characteristic “May,” “might,” “can” or “could” be included, for example, that particular component, feature, structure, or characteristic is not required to be included. If the specification or claims refer to “a” or “an” element, that does not mean there is only one of the element. If the specification or claims refer to “an additional” element, that does not preclude more than one of the additional element(s).

Although some aspects are described with reference to particular implementations, other implementations are possible according to some aspects. Additionally, the arrangement and/or order of elements or other features illustrated in the drawings or described herein need not be arranged in the particular way illustrated and described. Many other arrangements are possible according to some aspects.

In each figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

### Overview

At least some features disclosed herein relate to an open dielectric resonator with particles on a surface of the dielectric resonator, where the particles are configured to increase an amount of backscattered light within the dielectric resonator. The particles may be, for example, nanoparticles or fine particles that are located, distributed, positioned, sized and/or shaped to create, control, modulate and/or adjust one or more plasmons in the resonator to, for example, provide for (substantially) lossless, coherent backscattering of light. In this regard, the plasmons may allow for lossless or substantially lossless backscattering in the cavity. The plasmons do not themselves increase the amount of resonance of light in the cavity. Thus, a distinction may be drawn between the resonance of light in the cavity and any resonance of the plasmons (i.e. “plasmon resonance”). The plasmons may also be regarded as introducing a coupling between clockwise (CW) and counter-clockwise (CCW) modes in the cavity, which is similar to coherent resonant backscattering. Note that the “configuration” of the particles may include the relative location, distribution, positioning, material, size and/or shape, etc., of the particles, and so configuring the particles may include, e.g., determining the preferred or optimal locations to position the particles on the resonator surface and/or determining the preferred or optimal sizes, shapes and/or materials of the particles themselves.

At least some other features disclosed herein relate to a laser system having a laser configured to provide a laser beam having a laser frequency and a plasmon-activated cavity. The plasmon-activated cavity may be optically coupled to the laser and configured to (a) receive a portion of the laser beam, (b) scatter the portion of the laser beam in accordance with a plasmon resonance, and (c) feed at least some of the laser beam back to the laser for self-injection locking of the laser. The plasmon-activated cavity may be an open dielectric resonator provided with particles, such as nanoparticles, configured to increase an amount of plasmon resonance within the resonator or to provide a selected amount of plasmon resonance. For example, the nanoparticles are located, sized and/or shaped to backscatter a portion of the laser beam to provide an optical spectrum that overlaps with an optical wavelength of light circulating within the resonator cavity and to provide for (substantially) lossless, coherent backscattering. In some examples, the plasmon-activated cavity may be configured to stabilize the laser to a frequency of a plasmon mode to reduce a linewidth of the laser.

Still other features disclosed herein relate to a method of controlling a laser where a portion of a laser beam is coupled into a plasmon-activated cavity, in which the beam is scattered in accordance with a plasmon resonance. At least some of the scattered laser beam is fed back to the laser for self-injection locking of the laser. The plasmon-activated cavity may be a dielectric resonator provided with particles for increasing an amount of plasmon resonance within the dielectric resonator.

Herein, a “dielectric resonator” is a dielectric (nonconductive) material configured as an electromagnetic (EM) wave resonator. The exemplary dielectric resonators described herein are primarily optical micro-cavity resonators in which light propagates, but dielectric resonators may function at other EM wavelengths such microwave or millimeter wavelengths. Within an optical dielectric resonator, at least a portion of the light is confined to propagate or circulate within the dielectric material due to changes in permittivity at the surface of the material. At resonant frequencies, the light forms standing waves within the resonator, which may oscillate with large amplitudes. Dielectric resonators often comprise a bulk (sometimes called a puck) of dielectric material having a relatively high dielectric constant and a relatively low dissipation factor. The resonant frequency may be specified by the dimensions of the resonator material and the dielectric constant of the material. An “open” optical dielectric resonator is a resonator configured to permit light to be injected into the resonator and to permit at least a portion of the light to later emerge from the resonator.

Herein, a “micro-cavity” is a miniature-sized or micro-sized cavity device, i.e. a cavity device having very small features, such as features formed on the scale of microns (micrometers). A “monolithic micro-cavity” device is such a device formed of a single structure, such as the aforementioned dielectric resonators formed from a single crystalline or ceramic puck or bulk.

Herein, “nanoparticles” refer to particles on a nanoscale, i.e. particles in the range of 1 to 100 nanometers (nm), inclusive. Nanoparticles may also be referred to as ultrafine particles. Nanoparticles may have size-dependent properties due an interfacial layer consisting of, e.g., ions. An exemplary nanoparticle that may be deposited on the outer surface of the bulk of the dielectric resonator is a gold nano-particle.

Herein, “fine particles” refer to particles having diameters in the range of 100 nm to 2500 nm (or 2.5 microns). An exemplary fine particle that may be deposited on the outer surface of the dielectric resonator is a 250 nm-diameter gold particle.

Herein, “plasmon” refers to a quantum of plasma oscillation, such as a quantum or quasiparticle associated with a local collective oscillation of charge density. For example, at optical frequencies, a plasmon may couple with a photon to create another quasiparticle referred to as a plasmon polariton.

Examples and implementations of techniques and devices described herein may use optical resonators formed with plasmon-activated cavities in various configurations for self-injection locking based on reflection feedback. Specific examples provided herein include open dielectric resonators such as optical ring resonators and sphere and non-sphere whispering gallery mode (WGM) resonators including disk and ring shaped WGM resonators. An open dielectric resonator, such as a WGM resonator, can be configured to provide high resonator Q factors to provide both the optical filtering and injection feedback based on the reflection feedback from feedback optics outside the optical resonator. Such resonators confine light so that it is totally (or almost totally) reflected within a closed circular optical path. Under proper coupling conditions, light confined in the resonator can be coupled out of the exterior surface of the closed circular optical path of the resonator via the evanescence field.

An optical coupler can be used to couple light into or out of the resonator via the evanescent field. As an example, a semiconductor laser can be directly coupled to a high quality factor Q open dielectric resonator via optical coupling in an optical injection design to stabilize the laser. A portion of the light passing through the resonator is reflected back to the laser to lock the laser frequency (wavelength) to the frequency of the high Q mode of the resonator and to also narrow its spectral line. If the resonator is stabilized against environmental perturbations such as temperature variations or vibration, the stability of the modal frequency of the resonator is transferred to the laser frequency or wavelength.

Self-injection locking can significantly increase stability and spectral purity of lasers in various configurations. The locking is based on presence of a master cavity pumped with the laser. The self-injection is based on resonant Rayleigh scattering (scattering without frequency change) of light inside the optical resonators to produce a counter-propagating light beam in the opposite direction of the laser beam from the laser that is initially coupled into the optical resonators. The counter-propagating light beam inside the optical resonator is injected back to the laser.

Depending on the power level of the injected light fed back to the laser, various operating conditions may be established in the laser (where in some cases as the result of the back-scattering, the laser frequency becomes locked to the optically pumped mode of the master cavity the Rayleigh scattering originates from). If the optical feedback is sufficiently strong (e.g. above a certain threshold level), the master cavity functions as an external cavity for the laser to achieve both injection locking and modification of the lasing threshold of the laser operation where the master cavity modifies the threshold conditions of the lasing. When the optical feedback from the master cavity is relatively weak (e.g. below the certain threshold level), the lasing threshold of the laser is not significantly changed by the optical feedback but its stability still can be improved significantly via the injection locking. (If the Rayleigh scattering is too weak, the optical feedback from the injection can be at a low level that is insufficient to establish injection locking of the laser frequency to the mode of the master cavity.) The techniques of reflection feedback described in this disclosure can be used to provide desired or optimal feedback regimes for injection locking. In some applications, the laser devices described in this disclosure can be used in various devices such as opto-electronic oscillators, optical/photonic RF and microwave receivers, optical comb generators and narrow-linewidth lasers.

### Illustrative Examples

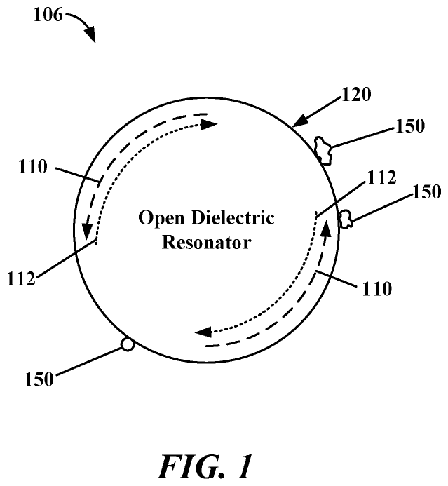

FIG. 1 illustrates a schematic representation of an optical resonator 106 according to one aspect. The optical resonator 106 may be, as indicated in the drawing figure, an open dielectric resonator. Light circulating within the resonator is shown by way of dashed lines 110. Backscattered light is shown by way of dotted lines 112. In this particular example, the light 110 propagates or circulates counter-clockwise. The backscattered light 112 propagates or circulates clockwise. Of course, the directions could be reversed. Backscattering within the resonator 106 is achieved using particles 150 having a selected or optimized location, size and/or shape, and which, depending on their size, may be nanoparticles or fine particles. (The particles are not shown to scale in the drawing figures.) The particles 150 may be made of one or more metals, such as gold, silver or platinum, and may be specifically-activated (see below) and then deposited at pre-treated locations (see below) of the resonator surface 120. As shown in FIG. 1, the particles 150 need not all have the same size and shape and may instead have different shapes and/or sizes, with some being relatively round, whereas others are more oblong, and with some relatively larger or smaller than others. The particles 150 have the capability to scatter light and thus serve as optical reflectors.

The particles are selectively or optimally located, sized and/or shaped to support a plasmon resonance providing (substantially) lossless and (substantially) coherent backscattering of light, where the backscattered light has an optical spectrum that (completely or substantially) overlaps with an optical wavelength of interest, i.e. the optical wavelength of interest is within the spectrum of backscattered light. Thus, placing subwavelength nanoparticles or fine particles on the surface of an open cavity resonator can result in resonant backscattering. The material used to form the particles also may be selected or optimized to support a plasmon mode that results in a resonant increase in backscattering. Notably, only a few nanoparticles placed on the resonator surface can result in significant backscattering. This can simplify the process of self-injection locking of a laser using the plasmon-activated open cavity. An open dielectric resonator provided with surface particles configured for supporting a plasmon resonance (such as resonator 106 of FIG. 1) may be referred to as a plasmon-activated resonator, a plasmon-activated cavity, or a plasmon-activated micro-cavity or by using other suitable terms.

Insofar as particle size is concerned, for light having longer wavelengths (e.g., 1550 nm), the particles 150 may be selected to be relatively large (e.g., fine particles having a diameter >100 nm). For light with shorter wavelengths (e.g., 750 nm), the particles 150 may be selected to be relatively small (e.g., nanoparticles having a diameter <100 nm). For any particular wavelength, otherwise routine experiments or tests may be performed to determine a size or range of sizes for the particles to achieve selected, desired, preferred or optimal amounts of backscattering and/or to achieve selected, desired, preferred or optimal backscatter spectra, and to determine suitable or optimal materials to use (e.g. gold). In one particular example, gold nanoparticles in the range of 50-100 nm in diameter might be used with wavelengths around 750 nm, whereas fine gold particles in the range of 150-350 nm might be used with wavelengths around 1550 nm. Note that if the particles are too small for the wavelength of the light, the plasmon frequency may be too large for the wavelength of the light and the backscattering effect thus may be too small. In such cases, increasing of the particle size may mitigate the issue. In some examples, the particles are no smaller than 10 nm and no larger than 500 nm.

Insofar as particle shape is concerned, otherwise routine experiments or tests may be performed to determine particle shapes suitable for achieving selected, desired, preferred or optimal amounts of backscattering and/or to achieve selected, desired, preferred or optimal backscatter spectra. For example, depending on the particular material used to form the particles (e.g. gold) and the wavelengths of interest, a suitable or optimal shape might be generally spherical (round), generally elliptical (oblong), generally disk-shaped, generally rod-shaped, or other suitable geometrical shapes.

Insofar as particle location, position, or distribution is concerned, otherwise routine experiments or tests may be performed to determine particle locations, positions, or distributions suitable for achieving selected, desired, preferred or optimal amounts of backscattering and/or to achieve selected, desired, preferred or optimal backscatter spectra. For example, two particles of different morphology may be used with the different particles placed in certain particular locations on the resonator surface relative to one another to achieve a desired functionality.

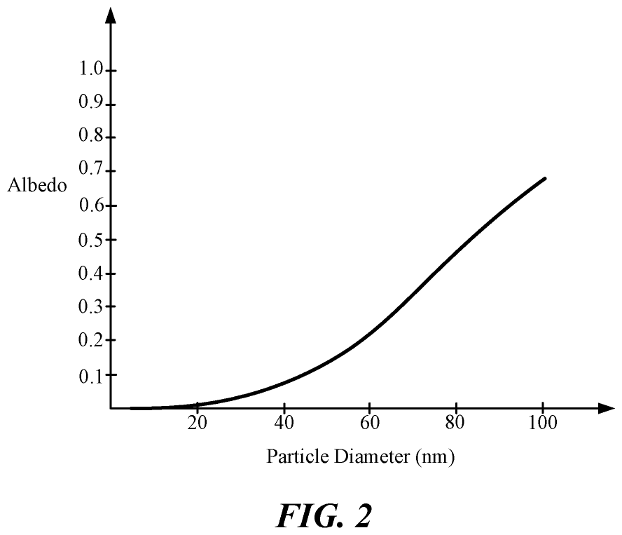

FIG. 2 provides a chart showing the “albedo” of an exemplary gold nanoparticle. The albedo is the ratio of light scattering to total optical loss (scattering plus absorption). The high albedo particles having a diameter smaller than half of the wavelength of the light of interest act as a highly efficient reflector if deposited at the resonator surface. For particles exceeding 100 nm, the plasmon-mediated scattering at 1550 nm may be optimal, whereas smaller particles have plasmon modes at higher frequencies.

Referring again to FIG. 1, it is noted that simply depositing particles 150 on the outer surface 120 of the optical resonator 106 may not be ideal if the particles can move or fall off. Unwanted displacement of the particles 150 can change the scattering efficiency and self-injection locking range of the laser. Unwanted displacement can be reduced by roughly polishing specific portions of the outer surface 120 where the particles 150 are then placed. That is, portions of the surface 120 may be “pre-treated” by roughly polishing those areas. Other forms of pre-treatment of the resonator surface may be useful as well, such as by treating the surface areas with suitable compounds before the particles are applied. The particles themselves may also be pre-treated so as to specifically activate the particles. For example, the particles may be chemically-activated to form chemical bonds between the particle and the surface 120. One example of a method for chemically-activating the particles is to pre-treat the particles by cleaning with alcohol and/or with the application of ultraviolet (UV) light. At least some of the particles may be covered with a thin polymer layer for better bonding. The pre-treatment may be performed before the particles are deposited unto the surface of the resonator.

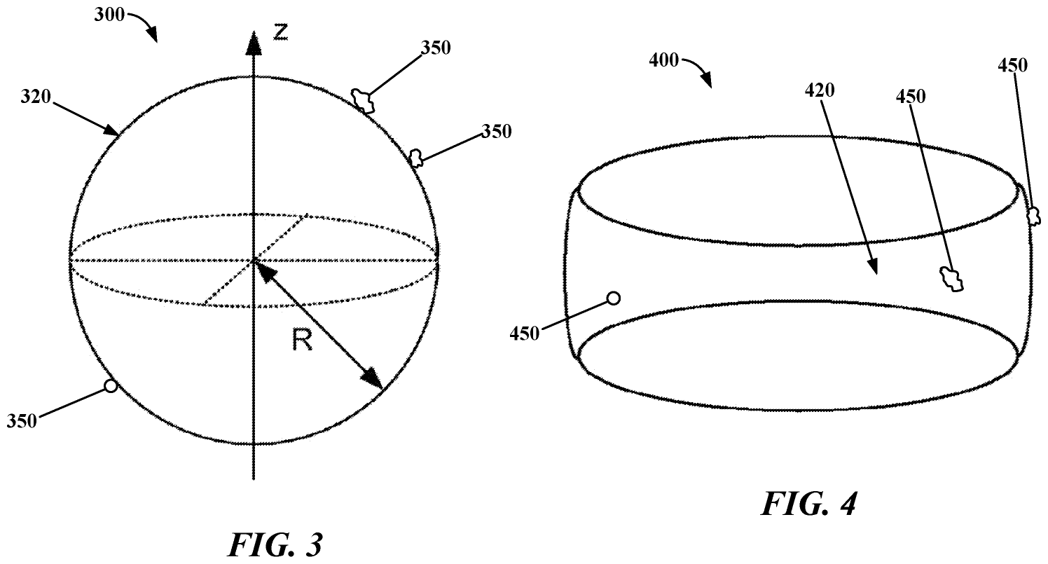

FIGS. 3-6 illustrate non-exclusive, non-limiting examples of open, dielectric resonators that include nanoparticles to provide plasmon resonance backscattering.

FIG. 3 illustrates a solid, spherical dielectric open resonator 300 having nanoparticles 350 secured to its outer surface 320. The nanoparticles 350 may be placed at pre-treated locations where the surface 320 has been roughly polished. The nanoparticles 350 are positioned, sized and shaped to support a plasmon resonance providing a lossless, coherent backscattering where the backscattered light has an optical spectrum that overlaps with the optical wavelength of interest that will resonate within the resonator 300. As already explained, the location, size, shape, and/or material of the nanoparticles may be optimized to achieve a sufficient or optimal plasmon resonance. In some cases, the particles are fine particles, rather than nanoparticles. Similar considerations apply to the examples of FIGS. 4-6 or to other figures described herein.

FIG. 4 illustrates a solid, disc-shaped dielectric open resonator 400 having nanoparticles 450 secured to its outer surface 420. The nanoparticles 450 may be placed at pre-treated locations that have been roughly polished. The nanoparticles 450 are sized and shaped to support a plasmon resonance providing a lossless, coherent backscattering where the backscattered light has an optical spectrum that overlaps with the optical wavelength of interest that will resonate within the resonator 400.

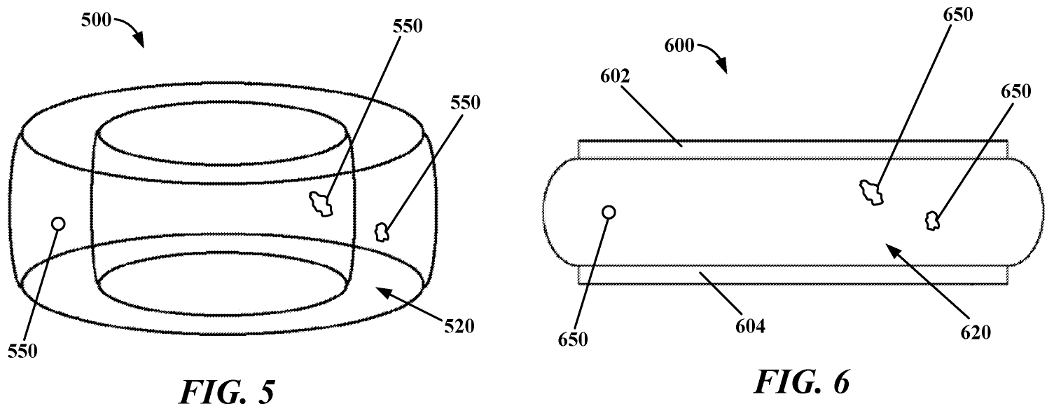

FIG. 5 illustrates a ring-shaped dielectric open resonator 500 having of nanoparticles 550 secured to its outer surface 520. The nanoparticles 550 may be placed at pre-treated locations on the surface 520. The nanoparticles 550 are located, sized and shaped to support a plasmon resonance providing a lossless, coherent backscattering where the backscattered light has an optical spectrum that overlaps with the optical wavelength of interest that will resonate within the resonator 500.

FIG. 6 illustrates a tunable, dielectric open resonator 600 having nanoparticles 650 secured to its outer surface 620. The nanoparticles 650 may be placed at pre-treated locations where the surface 620. The nanoparticles 650 are optimally or selectively located, sized and shaped to support a plasmon resonance providing a lossless, coherent backscattering where the backscattered light has an optical spectrum that overlaps with the optical wavelength of interest that will resonate within the resonator 600. The tunable resonator 600 may be made of an electro-optic material (e.g., lithium niobate) and may include one or more electrodes 602, 604. An electric field may be applied across the electrodes 602, 604 to control the index of refraction of the electro-optic material and change the filter function of the resonator 600.

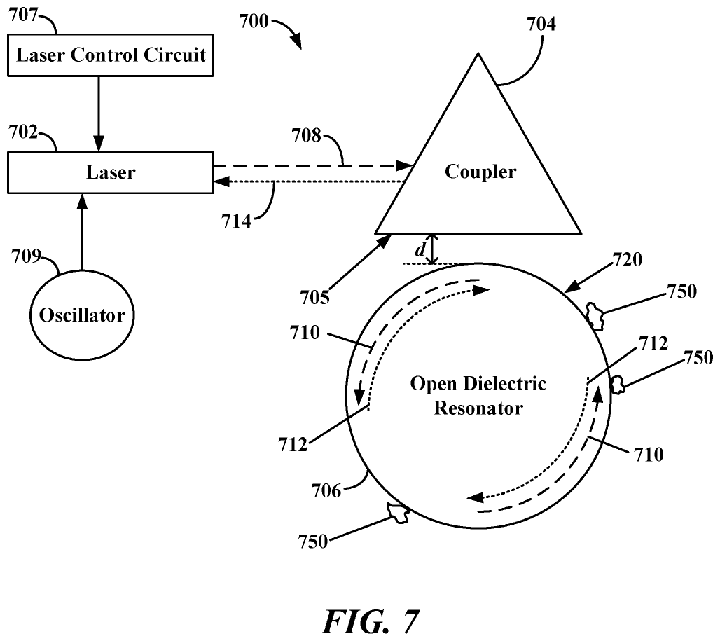

FIG. 7 illustrates an example of a laser device 700, where a laser 702 is optically coupled to an open dielectric resonator 706, such as one of the resonators 106, 300, 400, 500, 600 described above, through an optical coupler 704. The laser 702 is stabilized to the optical resonator 706 via an optical feedback from the optical resonator 706. In some aspects, the laser 702 is tunable in response to a control signal from a laser control circuit 707 and may also be modulated by a control signal from an oscillator 709. The laser 702 produces a laser beam 708 having a frequency that may drift or fluctuate due to various factors. The optical resonator 706 is structured to support a whispering gallery mode 710 circulating in the optical resonator 706 in a first (counter-clockwise) direction. A counter propagating beam of light 712 may also circulate inside the optical resonator 706 in an opposite (clockwise) direction.

The optical resonator 706 is optically coupled to the laser 702 to receive a portion of the laser beam into the optical resonator 706 as the beam 710 in the whispering gallery mode. Backscattering inside the optical resonator 706 of the received beam 710 can produce the counter propagating beam 712 in the same whispering gallery mode. As described in detail below, backscattering is caused by metal (e.g., gold, silver, or platinum) nanoparticles or fine particles on the exterior surface 720 of the optical resonator 706. The counter propagating beam 712 can be coupled out of the optical resonator 706 as a beam 714 in the opposite direction of the incoming laser beam 708 and thus can be coupled into the laser 702 to achieve the injection locking.

In the example shown, the optical coupler 704 (e.g., a prism) is used to couple laser light from the laser 702 into the optical resonator 706 and to couple light (e.g., beam 712) out of the resonator 706 back to the laser 702. The optical coupler 704 may be spaced a distance d from the optical resonator 706. In some aspects, a lens assembly (not shown) is placed between the optical coupler 704 and the laser 702 and is used to direct the laser light 714 back to the laser 702 to stabilize the frequency of the laser.

Fine particles having a diameter of approximately 250 nm may achieve significant enhancement of self-injection locking. Test results with CaF₂ resonators with a few gold particles of 250 nm diameter show a one hundred times extension in injection locking range, while MgF₂ resonators with such particles show ten times the injection locking range extension with (substantially) no extra mode crosstalk.

In some aspects, the optical resonator 706 is made from an electro-optic material and is tuned by changing an electrical control signal applied to the material (such as by using the electrodes of FIG. 6). Because of the optical injection locking, the laser wavelength or frequency can be tuned with the application of a direct current (DC) voltage applied to the resonator. Additionally or alternatively, a microwave or radio-frequency (RF) field may be applied to a suitably-configured resonator, where the field has a frequency that matches one or more free spectral range(s) of the resonator. As such, the laser frequency can be phase and/or amplitude modulated. Since the modal frequency of the resonator can be varied by application of temperature, pressure, or in the case of resonators made with electro-optic material, an applied DC potential, the frequency (wavelength) of the laser can also be tuned. Furthermore, the laser remains locked in frequency (wavelength) to the resonator if the frequency of the laser is modulated through the application of a microwave signal to the DC current applied to the laser 702. Thus a modulatable, narrow linewidth laser is provided. When the resonator 706 is made of an electro-optic material, a microwave or RF field can be applied to the resonator with the appropriate coupling circuitry to modulate the intensity of the laser 702, which continues to remain locked to the resonator.

### Summary of General Features and Embodiments

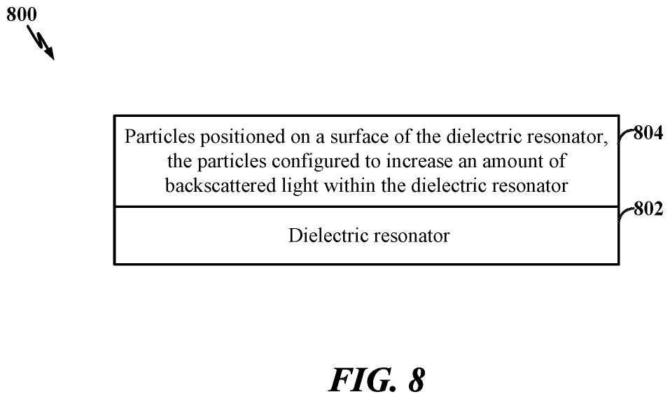

FIG. 8 summarizes general features of an exemplary resonator apparatus 900. Briefly, a dielectric resonator 802 is provided, which may be, for example, an open dielectric resonator. Particles 804 are positioned (e.g. secured) on a surface of the dielectric resonator, the particles configured to increase an amount of backscattered light within the dielectric resonator. Examples of resonator apparatus are described above.

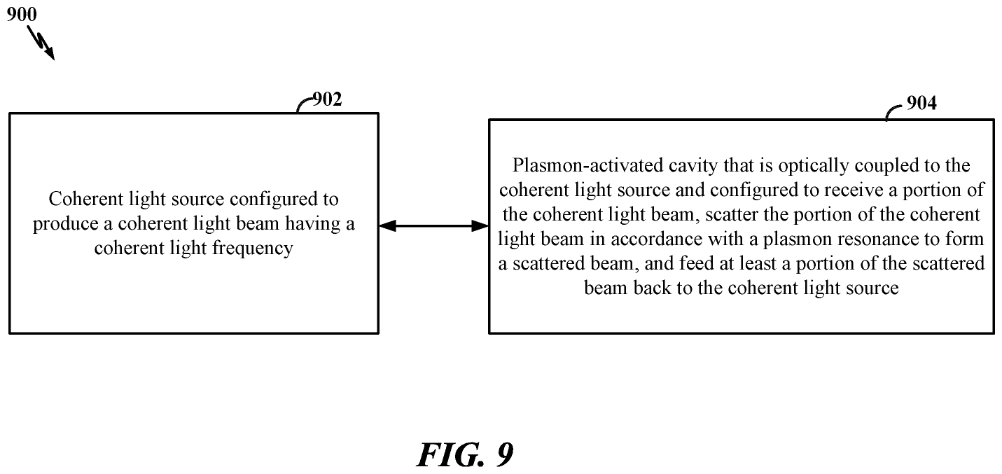

FIG. 9 summarizes general features of an exemplary optical system 900. Briefly, a coherent light source 902 is configured to produce a coherent light beam having a coherent light frequency. A plasmon-activated cavity 904 is provided that is optically coupled to the coherent light source and configured to receive a portion of the coherent light beam, scatter the portion of the coherent light beam in accordance with a plasmon resonance to provide a scattered beam, and feed at least a portion of the scattered beam back to the coherent light source. Examples are described above where the coherent light source is a laser.

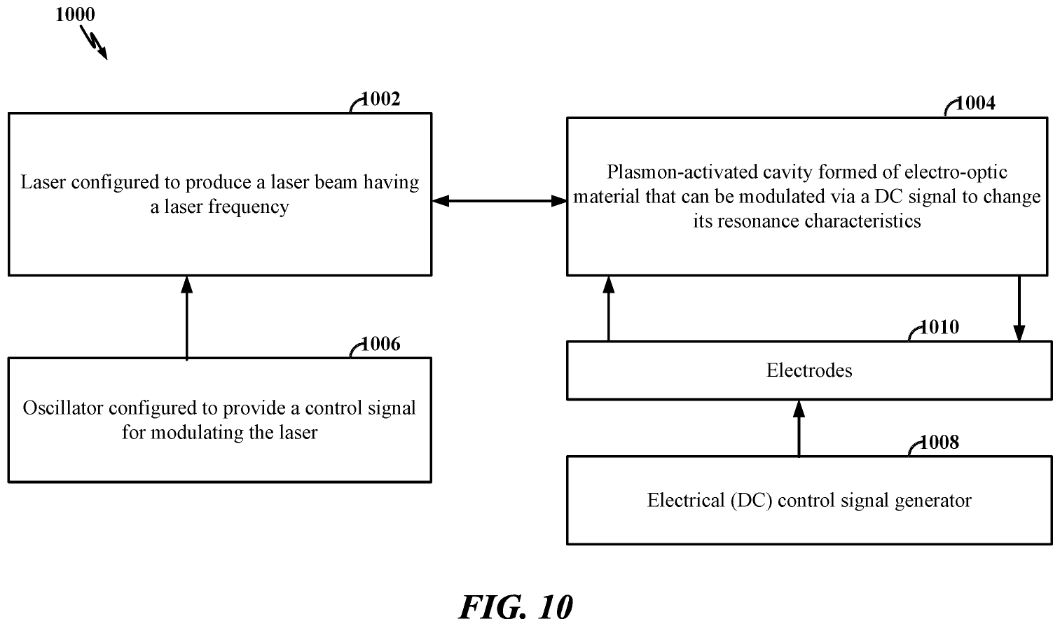

FIG. 10 summarizes general features of another exemplary optical system 1000. A laser 1002 is configured to produce a laser beam having a laser frequency. A plasmon-activated cavity 1004 formed of an electro-optic material is coupled to the laser 1000 where the electro-optic material can be modulated via a DC signal to change its resonance characteristics. An oscillator 1006 is coupled to the laser 1002. The oscillator 1006 is configured to provide a control signal for modulating the laser 1002. An electrical DC control signal generator is configured to provide a DC control signal for controlling the plasmon-activated cavity 1004. The DC control signal is applied to the plasmon-activated cavity 1004 via electrode(s) 1010. See, for example, FIG. 6 for a more detailed description of an apparatus where an electric field is applied across electrodes to control an index of refraction of an electro-optic material of cavity to modulate the cavity.

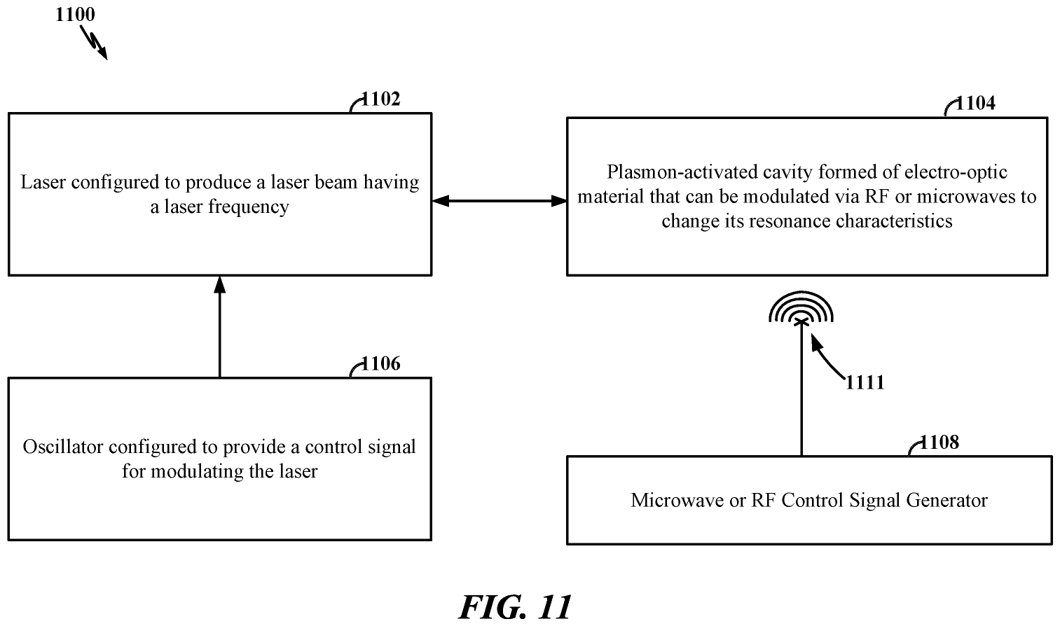

FIG. 11 summarizes general features of yet another exemplary optical system 1100. A laser 1102 is configured to produce a laser beam having a laser frequency. A plasmon-activated cavity 1104 formed of an electro-optic material is coupled to the laser 1100 where the electro-optic material can be modulated via RF or microwave signals to change its resonance characteristics. An oscillator 1106 is coupled to the laser 1102 to provide a control signal for modulating the laser 1102. A microwave or RF signal generator 1108 is configured to provide a microwave or RF control signal for controlling the plasmon-activated cavity 1104. The control signal is applied to the plasmon-activated cavity 1104 via an antenna 1110 or other suitable device for irradiating the material of the cavity with RF or microwave signals.

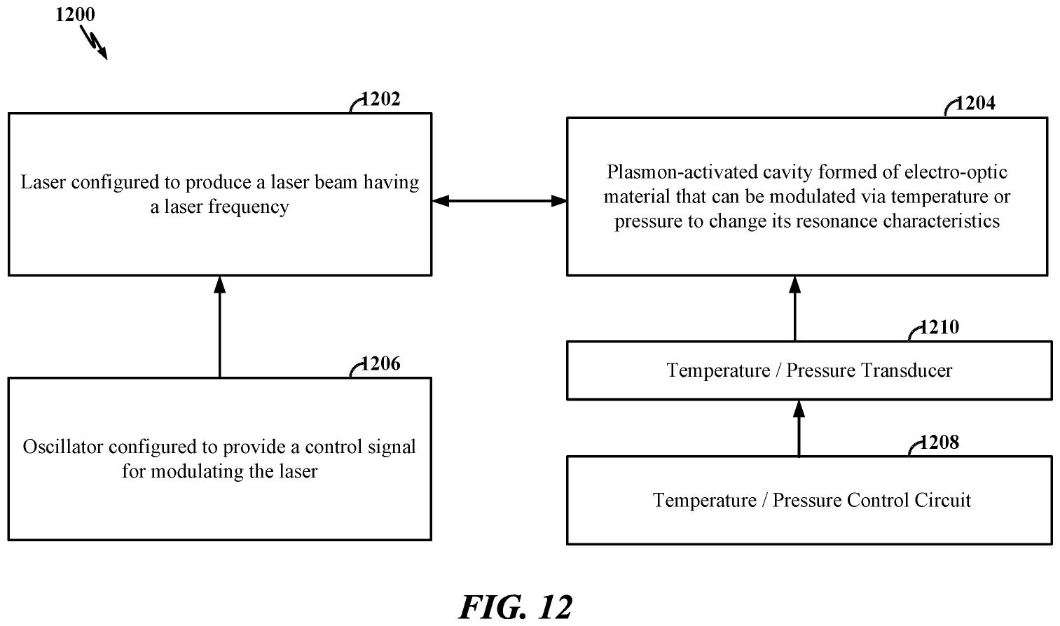

FIG. 12 summarizes general features of yet another exemplary optical system 1200. A laser 1202 is configured to produce a laser beam having a laser frequency. A plasmon-activated cavity 1204 formed of an electro-optic material is coupled to the laser 1200 where the electro-optic material can be modulated via temperature or pressure to change its resonance characteristics. An oscillator 1206 is coupled to the laser 1202 to provide a control signal for modulating the laser 1202. A temperature/pressure control circuit is configured to provide a temperature or pressure control signal for controlling the plasmon-activated cavity 1204. The control signal is applied to the plasmon-activated cavity 1204 via a temperature or pressure transducer 1210 or other suitable device for adjusting the temperature of the cavity 1204 or for applying pressure to the cavity to, for example, selectively squeeze or expand the cavity.

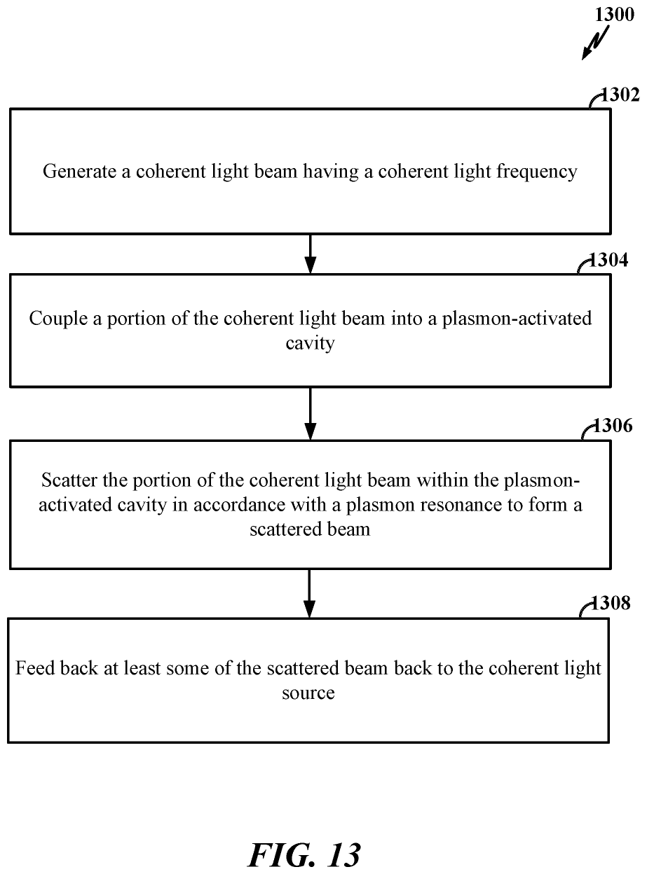

FIG. 13 summarizes general features of an exemplary method 1300 that may be used to, for example, to control an optical system such as the system of FIG. 8. At block 1302, a coherent light source generates a coherent light beam having a coherent light frequency. At block 1304, a portion of the coherent light beam is coupled into a plasmon-activated cavity using, for example, a coupler (such as a prism). At block 1306, the plasmon-activated cavity scatters the portion of the coherent light beam in accordance with a plasmon resonance to form a scattered beam (which may be, e.g., a backscattered laser beam). At block 1308, at least a portion of the scattered (e.g. backscattered) beam is fed back to the coherent light source using, e.g., the same coupler. As already explained, the coherent light source may be a laser and the feedback signal may be used to self-injection lock the laser.

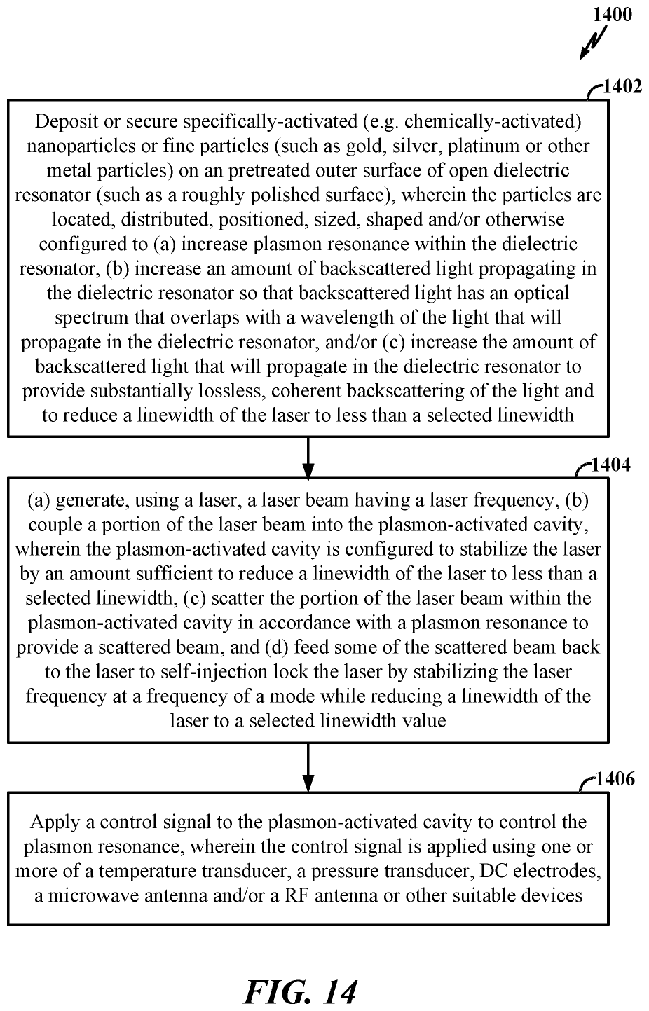

FIG. 14 summarizes further features of an exemplary method 1900 that may be used to, for example, to control a laser system such as the laser systems of FIG. 7. At block 1402, specifically-activated (e.g. chemically-activated) nanoparticles or fine particles (such as gold, silver, platinum or other metal particles) are deposited or secured on an pretreated outer surface of an open dielectric resonator (such as a roughly polished surface), wherein the particles are located, distributed, positioned, sized, shaped and/or otherwise configured to (a) increase a plasmon resonance within the dielectric resonator, (b) increase an amount of backscattered light propagating in the dielectric resonator so that the backscattered light has an optical spectrum that overlaps with a wavelength of the light that will propagate in the dielectric resonator, and/or (c) increase an amount of backscattered light that will propagate in the dielectric resonator to provide substantially lossless, coherent backscattering of the light and to reduce a linewidth of the laser to less than a selected linewidth. The nanoparticles or fine particles may be chemically-activated or pre-treated as discussed above to form chemical bonds between the particles and the surface of the resonator.

At block 1404, a laser beam is generated using a laser having a laser frequency and a portion of the laser beam is coupled into the plasmon-activated cavity, wherein the plasmon-activated cavity is configured to stabilize the laser by an amount sufficient to reduce a linewidth of the laser to less than a selected linewidth. The portion of the laser beam is scattered within the plasmon-activated cavity in accordance with a plasmon resonance to provide a scattered beam. Some of the scattered beam is fed back to the laser to self-injection lock the laser by stabilizing the laser frequency at a frequency of a mode and to reduce a linewidth of the laser to a selected linewidth value.

At block 1406, a control signal is applied to the plasmon-activated cavity by a control device to control, adjust or modulate the plasmon resonance, wherein the control signal is applied using one or more of a pressure transducer, a temperature transducer, DC electrodes, a microwave antenna and/or an RF antenna. See, the various examples discussed above.

The various components and functions shown in FIGS. 1-14 may be replaced with a suitable means for performing or controlling corresponding operations. Hence, in at least some examples, an apparatus may include one or more of: means for producing a coherent light beam having a coherent light frequency; means for receiving a portion of the coherent light beam; means for scattering the portion of the coherent light beam in accordance with a plasmon resonance to provide a scattered beam; and means for feeding at least a portion of the scattered beam back to the coherent light source. The means for producing a coherent light beam may be a laser and the means for scattering the portion of the coherent light beam in accordance with a plasmon resonance to provide a scattered beam may be a plasmon-activated cavity. The apparatus may include: means for providing a control signal for modulating the laser; means for providing a control signal for controlling the plasmon-activated cavity. The means for providing a control signal for controlling the plasmon-activated cavity may include one or more of: means for applying a DC control signal to the plasmon-activated cavity; means for applying a temperature control signal to the plasmon-activated cavity; means for applying a pressure control signal to the plasmon-activated cavity; means for applying a microwave control signal to the plasmon-activated cavity; and means for applying an RF control signal to the plasmon-activated cavity.

One or more of the components, steps, features, and/or functions illustrated in FIGS. 1, 2, 3, 4, 5, 6, 7, 8, 9, 10, 11, 12, 13, and/or 14 may be rearranged and/or combined into a single component, step, feature or function or embodied in several components, steps, or functions. Additional elements, components, steps, and/or functions may also be added without departing from the disclosure. Any control algorithms described herein may be implemented in software and/or in hardware.

The various features of the invention described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A resonator apparatus comprising:
a dielectric resonator; and
particles positioned on a surface of the dielectric resonator, the particles configured to increase an amount of backscattered light within the dielectric resonator.

2. The resonator apparatus of claim 1, wherein the particles comprise one or more of nanoparticles and fine particles.

3. The resonator apparatus of claim 2, wherein the particles are metal nanoparticles.

4. The resonator apparatus of claim 1, wherein the apparatus is configured to provide for plasmon resonance.

5. The resonator apparatus of claim 4, wherein the particles are located, distributed, positioned, sized and/or shaped to increase the amount of backscattered light within the dielectric resonator.

6. The resonator apparatus of claim 1, wherein the particles are configured to backscatter light propagating in the dielectric resonator, the backscattered light having an optical spectrum overlapping a wavelength of the light propagating in the dielectric resonator.

7. The resonator apparatus of claim 1, wherein the particles are configured to backscatter light propagating in the dielectric resonator to provide substantially lossless, coherent backscattering of the light propagating in the dielectric resonator.

8. The resonator apparatus of claim 1, wherein the dielectric resonator is an open dielectric resonator.

9. The resonator apparatus of claim 1, wherein the dielectric resonator is configured as one or more of an optical ring resonator, a spherical whispering gallery mode (WGM) resonator, disk-shaped WGM resonator, a ring-shaped WGM resonator.

10. An optical system comprising:
a coherent light source configured to provide a coherent light beam having a coherent light frequency; and
a plasmon-activated cavity, optically coupled to the coherent light source, and configured to receive a portion of the coherent light beam, scatter the portion of the coherent light beam in accordance with a plasmon resonance to form a scattered beam, and feed at least a portion of the scattered beam back to the coherent light source.

11. The optical system of claim 10, wherein the coherent light source is a laser and the plasmon-activated cavity is configured to stabilize the laser to a frequency of a plasmon mode.

12. The optical system of claim 11, wherein the plasmon-activated cavity is configured to stabilize the laser by an amount sufficient to reduce a linewidth of the laser to less than a selected linewidth.

13. The optical system of claim 10, wherein particles are deposited on an outer surface of the plasmon-activated cavity.

14. The optical system of claim 13, where the particles are located, distributed, positioned, sized and/or shaped to achieve a selected amount of plasmon resonance.

15. The optical system of claim 13, where the particles are located, distributed, positioned, sized and/or shaped to backscatter the portion of the coherent light beam to provide backscattered light with an optical spectrum overlapping an optical wavelength of light circulating in the cavity.

16. The optical system of claim 13, wherein the particles are located, distributed, positioned, sized and/or shaped to backscatter light circulating in the plasmon-activated cavity to provide substantially lossless, coherent backscattering of the light circulating in the plasmon-activated cavity.

17. A method of controlling a coherent light source, comprising:
generating a coherent light beam having a coherent light frequency;
coupling a portion of the coherent light beam into a plasmon-activated cavity;
scattering the portion of the coherent light beam within the plasmon-activated cavity in accordance with a plasmon resonance to form a scattered beam; and
feeding at least a portion of the scattered beam back to the coherent light source from the plasmon-activated cavity.

18. The method of claim 17, further comprising applying a control signal to the plasmon-activated cavity to control the plasmon resonance.

19. The method of claim 17, further comprising, before coupling the portion of the coherent light beam into the plasmon-activated cavity, depositing particles on an outer surface of the plasmon-activated cavity, the particles configured to increase an amount of backscattered light within the plasmon-activated cavity.

20. The method of claim 19, wherein the coherent light source is a laser and the particles are configured to reduce a linewidth of the laser to less than a selected linewidth.
